(19) United States
(12) Patent Application Publication
(10) Pub. No.: US 2024/0414991 A1
(43) Pub. Date: Dec. 12, 2024

(54) SELF-LUMINOUS DISPLAY DEVICE

(71) Applicant: AGC Inc., Tokyo (JP)

(72) Inventors: Katsumi SUZUKI, Tokyo (JP); Kazuya Takemoto, Tokyo (JP)

(73) Assignee: AGC Inc., Tokyo (JP)

(21) Appl. No.: 18/813,331

(22) Filed: Aug. 23, 2024

Related U.S. Application Data
(63) Continuation of application No. PCT/JP2023/006320, filed on Feb. 21, 2023.

(30) Foreign Application Priority Data
Feb. 28, 2022 (JP) 2022-030295

(51) Int. Cl. H10K 59/80; G02B 1/11; H01L 33/58

(52) U.S. Cl. CPC H10K 59/8791; G02B 1/11; H01L 33/58

(57) ABSTRACT

A self-luminous display device includes an anti-reflective film-attached transparent substrate including a transparent substrate and an anti-reflective film on the transparent substrate. The anti-reflective film has a light absorption ability and has a laminated structure in which at least two dielectric layers having different refractive indices are laminated.

### CROSS-REFERENCE TO RELATED APPLICATIONS

This is a bypass continuation of International Patent Application No. PCT/JP2023/006320, filed on Feb. 21, 2023, which claims priority to Japanese Patent Application No. 2022-030295, filed on Feb. 28, 2022. The contents of these applications are hereby incorporated by reference in their entireties.

### TECHNICAL FIELD

The present invention relates to a self-luminous display device.

### BACKGROUND ART

Self-luminous display devices such as an organic light-emitting diode (OLED) display device (organic EL display device) and a micro LED display device do not require backlights, unlike liquid crystal displays, and can be made thinner and lighter. In addition, since it is driven by self-luminescence of a LED chip, it has advantages of a high luminance and a wide viewing angle.

The OLED display device generally includes a light emitting element in which an organic light emitting layer is sandwiched between electrodes (an anode and a cathode). In order to extract light from the light emitting layer, one electrode is often made of a transparent material such as ITO (indium tin oxide, indium oxide doped with tin), and the other electrode is made of a highly reflective metal material. These metal materials have a very high reflectance and reflect external light (for example, external lighting and natural light) directly. Therefore, there is a problem with the light reflected from the display degrading display performance, resulting in a reduced contrast and glare caused by the electrodes reflecting the external light.

In addition, in the micro LED display device, reflection of external light is problematic in a portion of the entire region of a substrate where no LED chip is mounted, that is, in an exposed substrate region between adjacent pixels. Particularly, in the case where a partial region of an electrode pad formed on the substrate to correspond to a corresponding micro LED chip, for electrically connecting electrodes of micro LED chips, is exposed, the reflection of the external light from the exposed partial region of the electrode pad is more pronounced. In this way, there are also problems such as a reduced display contrast and glare caused by the reflection of the external light from the electrode pad and the reflection of the external light from the exposed substrate region.

In order to prevent the above glare, for example, it has been proposed to dispose a polarizing plate on a viewing side of an OLED display device (for example, Patent Literature 1), but this leads to poor light utilization efficiency due to absorption by the polarizing plate, a lower luminance, and an increased production cost.

On the other hand, Patent Literature 2 discloses an optical laminate for use in a self-luminous display device, including a substrate having one surface subjected to an anti-reflective treatment and/or an anti-glare treatment, and an adhesive layer containing a colorant, and the colorant contained in the adhesive layer absorbs visible light, thereby preventing the above glare caused by the reflection of the external light.

### CITATION LIST

### Patent Literature

Patent Literature 1: JP2003-332068A
Patent Literature 2: JP2021-160242A

### SUMMARY OF INVENTION

### Technical Problem

However, in the case where the optical laminate in Patent Literature 2 is used in a self-luminous display device, the external light reaches the substrate subjected to an anti-reflective treatment and/or an anti-glare treatment before reaching the adhesive layer. Therefore, when the external light is reflected by the substrate surface, the amount of light that reaches the adhesive layer is reduced. As a result, the colorant contained in the adhesive layer cannot efficiently absorb incident light and reflected light from an interface with a lower layer, resulting in problems such as a poor display contrast and poor visibility.

Therefore, an object of the present invention is to provide a self-luminous display device that sufficiently prevents glare of external light and increases a display contrast.

### Solution to Problem

The present invention is as follows.
(1) A self-luminous display device including an anti-reflective film-attached transparent substrate including a transparent substrate and an anti-reflective film on the transparent substrate, in which the anti-reflective film has a light absorption ability and has a laminated structure in which at least two dielectric layers having different refractive indices are laminated.
(2) The self-luminous display device according to the above (1), in which the anti-reflective film-attached transparent substrate has a luminous transmittance (Y) of 20% to 90%.
(3) The self-luminous display device according to the above (1) or (2),
in which at least one of the dielectric layers is mainly formed of an oxide of Si,
at least another layer among layers in the laminated structure is mainly formed of a mixed oxide of an oxide containing at least one selected from the group A consisting of Mo and W and an oxide containing at least one selected from the group B consisting of Si, Nb, Ti, Zr, Ta, Al, Sn, and In, and
a content of elements of the group B contained in the mixed oxide is 65 mass % or less with respect to a total of elements of the group A contained in the mixed oxide and the elements of the group B contained in the mixed oxide.
(4) The self-luminous display device according to any one of the above (1) to (3), in which a ratio of a diffuse reflectance (SCE Y) on an outermost surface of the anti-reflective film-attached transparent substrate to a luminous reflectance (SCI Y) on the outermost surface of the anti-reflective film-attached transparent substrate, SCE Y/SCI Y, is 0.15 or more.
(5) The self-luminous display device according to any one of the above (1) to (4), in which the luminous reflectance (SCI Y) on an outermost surface of the anti-reflective film-attached transparent substrate is 1.5% or less.
(6) The self-luminous display device according to any one of the above (1) to (5), in which the diffuse reflectance (SCE Y) on an outermost surface of the anti-reflective film-attached transparent substrate is 0.05% or more.
(7) The self-luminous display device according to any one of the above (1) to (6), having a b* value in a transmission color under a D65 light source of 5 or less.
(8) The self-luminous display device according to any one of the above (1) to (7), having a haze value of 1% or more.
(9) The self-luminous display device according to any one of the above (1) to (8), in which the anti-reflective film has a sheet resistance of 10⁴Ω/□ or more.
(10) The self-luminous display device according to any one of the above (1) to (9), including at least one of an anti-glare layer and a hard coat layer between the transparent substrate and the anti-reflective film.
(11) The self-luminous display device according to any one of the above (1) to (10), further including an antifouling film on the anti-reflective film.
(12) The self-luminous display device according to any one of the above (1) to (11), in which the transparent substrate includes a glass.
(13) The self-luminous display device according to any one of the above (1) to (12), in which the transparent substrate includes at least one resin selected from polyethylene terephthalate, a polycarbonate, acrylic, silicone, and triacetyl cellulose.
(14) The self-luminous display device according to any one of the above (1) to (13), in which the transparent substrate is a laminate including a glass and at least one resin selected from polyethylene terephthalate, a polycarbonate, acrylic, silicone, and triacetyl cellulose.
(15) The self-luminous display device according to the above (12) or (14), in which the glass is chemically strengthened.
(16) The self-luminous display device according to any one of the above (1) to (15), in which the transparent substrate has been subjected to an anti-glare treatment on a main surface having the anti-reflective film.
(17) The self-luminous display device according to any one of the above (1) to (16), which is an OLED display device or a micro LED display device.

### Advantageous Effects of Invention

According to one aspect of the present invention, it is possible to provide a self-luminous display device that sufficiently prevents glare of external light and increases a display contrast.

### BRIEF DESCRIPTION OF DRAWINGS

FIG. 1 is a cross-sectional view schematically showing a configuration example of a self-luminous display device according to an embodiment of the present invention.

FIG. 2 is a cross-sectional view schematically showing a configuration example of an OLED display device according to an embodiment of the present invention.

FIG. 3 is a cross-sectional view schematically showing a configuration example of a micro LED display device according to an embodiment of the present invention.

FIG. 4 is a cross-sectional view schematically showing a configuration example of an anti-reflective film-attached transparent substrate according to the present embodiment.

### DESCRIPTION OF EMBODIMENTS

Hereinafter, an embodiment of the present invention is described.

Note that, in the present description, “another layer, film, or the like being provided on a main surface of a transparent substrate, on a layer such as an anti-glare layer or a hard coat layer, or on a film such as an anti-reflective film” is not limited to an embodiment in which the another layer, film, or the like is provided in contact with the main surface, layer, or film, but may be an embodiment in which the layer, film, or the like is provided in an upward direction. For example, “an anti-glare layer or a hard coat layer being provided on a main surface of a transparent substrate” means that the anti-glare layer or the hard coat layer may be provided in contact with the main surface of the transparent substrate, or any other layer, film, or the like may be provided between the transparent substrate and the anti-glare layer or the hard coat layer.

### <Self-luminous Display Device>

A self-luminous display device according to an embodiment of the present invention includes an anti-reflective film-attached transparent substrate including a transparent substrate and an anti-reflective film on the transparent substrate, in which the anti-reflective film has a light absorption ability and has a laminated structure in which at least two dielectric layers having different refractive indices are laminated.

Examples of the self-luminous display device according to the embodiment of the present invention include an OLED display device and a micro LED display device.

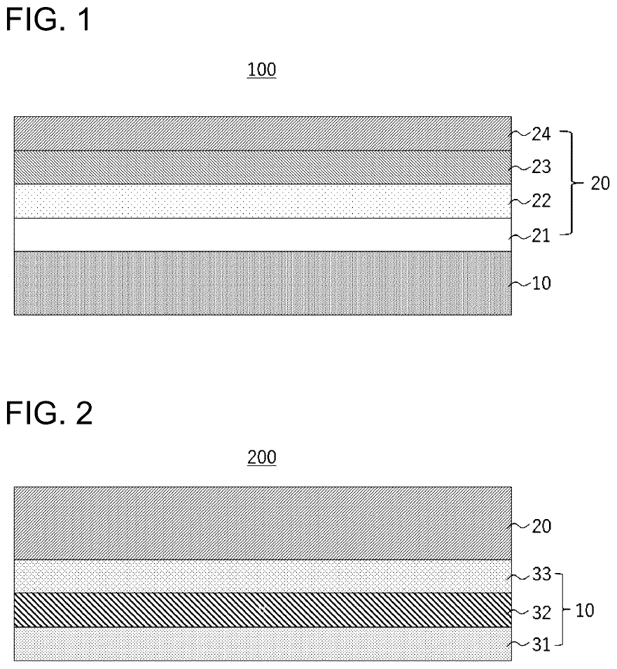

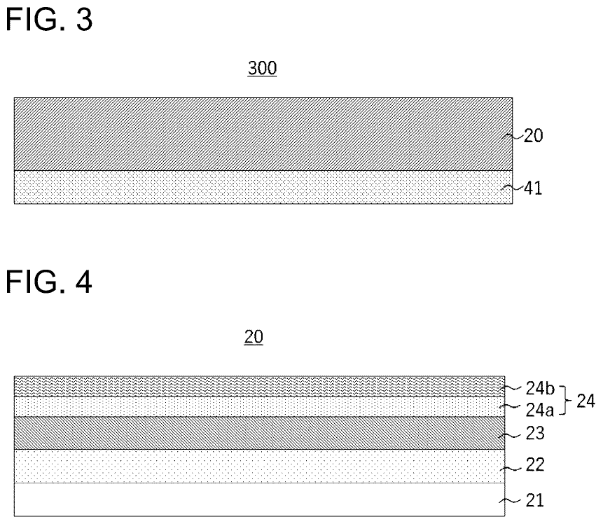

As shown in FIG. 1, a self-luminous display device 100 according to the embodiment of the present invention includes an anti-reflective film-attached transparent substrate 20 on a self-luminous display 10. The self-luminous display 10 includes a light emitting element, which is an OLED light emitting element 32 in the case of an OLED display device as shown in FIG. 2, and is a micro LED light emitting element 41 in the case of a micro LED display device as shown in FIG. 3.

FIG. 2 is a cross-sectional view schematically showing a configuration example of an OLED display device 200 according to an embodiment of the present invention. The OLED display device 200 according to the present embodiment includes a cathode 31, the OLED light emitting element 32, an anode 33, and the anti-reflective film-attached transparent substrate 20, in this order. The OLED light emitting element 32 can be those known in the related art, and includes, for example, an electron transport layer, a light emitting layer, and a hole transport layer. The cathode 31 and the anode 33 can also be those known in the related art.

FIG. 3 is a cross-sectional view schematically showing a configuration example of a micro LED display device 300 according to an embodiment of the present invention. The micro LED display device 300 according to the present embodiment includes the micro LED light emitting element 41 and the anti-reflective film-attached transparent substrate 20, in this order. The micro LED light emitting element 41 can be those known in the related art, and includes, for example, a micro LED, a semiconductor circuit (wiring/driving circuit), and a glass or plastic substrate.

### <Anti-Reflective Film-Attached Transparent Substrate>

Next, the anti-reflective film-attached transparent substrate 20 is described below. FIG. 4 is a cross-sectional view schematically showing a configuration example of the anti-reflective film-attached transparent substrate 20 according to the present embodiment. On a transparent substrate having two main surfaces (hereinafter, simply referred to as a transparent substrate) 22, an anti-glare layer or hard coat layer 23 is provided on one of the main surfaces as an optional layer, and an anti-reflective film (multilayer film) 24 is provided on the anti-glare layer or hard coat layer 23. In addition, an adhesive layer 21 may be provided on the main surface of the transparent substrate 22 on which the anti-glare layer or the hard coat layer is not provided. The anti-reflective film-attached transparent substrate 20 is attached to the self-luminous display 10 via the adhesive layer 21.

### <Transparent Substrate>

The transparent substrate in the present embodiment preferably has a refractive index of 1.4 or more and 1.7 or less. When the refractive index of the transparent substrate is within the above range, reflection at an adhesion surface can be sufficiently prevented in the case of optically adhering a display, a touch panel, or the like. The refractive index is more preferably 1.45 or more, still more preferably 1.47 or more, and is more preferably 1.65 or less, still more preferably 1.6 or less.

The transparent substrate preferably includes at least one of a glass and a resin. The transparent substrate more preferably includes both a glass and a resin.

In the case where the transparent substrate includes a glass, due to high surface flatness of the glass, a clear, high-quality image can be obtained by disposing the transparent substrate on a surface of a display.

In the case where the transparent substrate includes a resin, it is less likely to break due to an external impact, and is therefore safer than the glass. In addition, in the case where a transparent film such as PET or TAC is selected as the resin, continuous processing with a roll is possible in the case of forming an anti-glare layer as an anti-glare treatment, and the cost can be reduced. Further, by applying fine particles made of various materials for an anti-glare layer, there is another advantage that the design freedom of the anti-glare layer is increased compared to a method of etching a glass surface.

In the case where the transparent substrate includes both a glass and a resin, for example, a resin film having an anti-glare layer is attached to a glass, whereby the transparent substrate includes both the glass and the resin. Therefore, it is possible to combine the advantages of both the glass and the resin, such as the flatness of the glass, and a shatterproof function and high design freedom of the anti-glare layer due to the resin.

In the case where the transparent substrate includes a glass, the kind of the glass is not particularly limited, and glasses having various compositions can be used. Among them, the glass preferably contains sodium and preferably has a composition that allows molding and strengthening by a chemical strengthening treatment. Specific examples thereof include an aluminosilicate glass, a soda lime glass, a borosilicate glass, a lead glass, an alkali barium glass, and an aluminoborosilicate glass.

Note that, in the present description, in the case where the transparent substrate includes a glass, the transparent substrate is also called a glass substrate.

The thickness of the glass substrate is not particularly limited, and in the case of subjecting the glass to a chemical strengthening treatment, the thickness is generally preferably 5 mm or less, more preferably 3 mm or less, and still more preferably 1.5 mm or less, in order to effectively perform chemical strengthening. It is generally 0.2 mm or more.

The glass substrate is preferably a chemically strengthened glass obtained by chemical strengthening. Accordingly, the strength of the anti-reflective film-attached transparent substrate is increased. Note that, in the case where an anti-glare layer to be described later is provided on the glass substrate, the chemical strengthening is carried out after the anti-glare layer is provided and before the anti-reflective film (multilayer film) is formed.

In the case where the transparent substrate includes a resin, the kind of the resin is not particularly limited, and resins having various compositions can be used. Among them, the resin is preferably a thermoplastic resin or a thermosetting resin. Examples thereof include a polyvinyl chloride resin, a polyethylene resin, a polypropylene resin, a polystyrene resin, a polyvinyl acetate resin, a polyester resin, a polyurethane resin, a cellulose-based resin, an acrylic resin, an AS (acrylonitrile-styrene) resin, an ABS (acrylonitrile-butadiene-styrene) resin, a fluorine-based resin, a thermoplastic elastomer, a polyamide resin, a polyimide resin, a polyacetal resin, a polycarbonate resin, a modified polyphenylene ether resin, a polyethylene terephthalate resin, a polybutylene terephthalate resin, a polylactic acid-based resin, a cyclic polyolefin resin, and a polyphenylene sulfide resin. Among them, a cellulose-based resin is preferred, and examples thereof include a triacetyl cellulose resin, a polycarbonate resin, and a polyethylene terephthalate resin. These resins may be used alone or in combination of two or more kinds thereof.

The resin particularly preferably contains at least one resin selected from polyethylene terephthalate, a polycarbonate, acrylic, silicone, and triacetyl cellulose. These resins are preferred because of being colorless, transparent, highly transmissive, and low scattering, being readily available and therefore relatively inexpensive, and being capable of being used as a main component of a hard coat and an adhesive to impart functions.

Note that, in the present description, in the case where the transparent substrate includes a resin, the transparent substrate is also called a resin substrate.

The shape of the resin substrate is not particularly limited. Examples thereof include a film shape or a plate shape, and a film shape is preferred from the viewpoint of shatterproofness.

In the case where the resin substrate has a film shape, that is, when it is a resin film, the thickness is not particularly limited, and is preferably 20 μm to 250 μm, and more preferably 40 μm to 188 μm.

In the case where the resin substrate has a plate shape, that is, when it is a resin plate, the thickness is not particularly limited, and is preferably generally 5 mm or less, more preferably 3 mm or less, and still more preferably 1.5 mm or less. It is generally 0.2 mm or more.

In the case where the transparent substrate includes both a glass and a resin, for example, the resin substrate may be provided on the glass substrate.

### <Anti-Glare Layer and Hard Coat Layer>

At least one of an anti-glare layer and a hard coat layer may be provided on the surface of the transparent substrate in the present embodiment, on which an anti-reflective film to be described later is provided. That is, at least one of an anti-glare layer and a hard coat layer may be provided between the transparent substrate and the anti-reflective film.

In the case where the transparent substrate is a glass substrate, preferred is an embodiment in which an anti-glare layer is provided on the glass substrate. In the case where the transparent substrate is a resin substrate, preferred is an embodiment in which a hard coat layer is provided on the resin substrate, or an embodiment in which an anti-glare layer is provided on the resin substrate.

When the transparent substrate has an anti-glare layer on the main surface, that is, the surface of the transparent substrate is subjected to an anti-glare treatment, glare caused by light incident on a self-luminous display device can be prevented. In addition, when the transparent substrate such as a resin substrate has a hard coat layer on the main surface, the surface hardness is increased, and the scratch resistance is improved. That is, a surface protection function of the self-luminous display device is improved.

The anti-glare layer has irregularities on one surface thereof, and thus causes light scattering, increases the haze value, and imparts anti-glare properties. The anti-glare layer can be those known in the related art, and may be formed of, for example, an anti-glare layer composition obtained by dispersing a particulate substance at least having anti-glare properties per se in a solution in which a polymer resin is dissolved as a binder. The anti-glare layer can be formed, for example, by coating one main surface of the transparent substrate with the anti-glare layer composition.

Examples of the particulate substance having anti-glare properties include inorganic fine particles such as silica, clay, talc, calcium carbonate, calcium sulfate, barium sulfate, aluminum silicate, titanium oxide, synthetic zeolite, alumina, and smectite, and organic fine particles including a styrene resin, a urethane resin, a benzoguanamine resin, a silicone resin, an acrylic resin, or the like.

The hard coat layer can be those known in the related art, and may be formed of, for example, a hard coat layer composition containing a polymer resin to be described later. The hard coat layer can be formed by coating one main surface of the transparent substrate such as a resin substrate with the hard coat layer composition.

In addition, as the polymer resin as a binder for the anti-glare layer or the hard coat layer, for example, polymer resins such as a polyester resin, an acrylic resin, an acrylic urethane resin, a polyester acrylate resin, a polyurethane acrylate resin, an epoxy acrylate resin, and a urethane resin can be used.

Examples of a laminate including the transparent substrate and the anti-glare layer or the hard coat layer (hereinafter, simply referred to as a laminate) include a resin substrate-anti-glare layer, a resin substrate-hard coat layer, and a glass substrate-anti-glare layer.

Examples of the resin substrate-anti-glare layer include an anti-glare PET film and an anti-glare TAC film. Specifically, examples of the anti-glare PET film include trade name: EHC-10a manufactured by Higashiyama Film Co., Ltd., and those manufactured by REIKO Co., Ltd. In addition, examples of the anti-glare TAC film include trade name: VZ50 manufactured by TOPPAN TOMOEGAWA Optical Films Co., Ltd., and trade name: VH66H manufactured by TOPPAN TOMOEGAWA Optical Films Co., Ltd.

Examples of the resin substrate-hard coat layer include a hard coat PET film and a hard coat TAC film. Specifically, examples of the hard coat PET film include trade name: TUFTOP manufactured by TORAY INDUSTRIES, INC., and trade name: KB Film G01S manufactured by KIMOTO Co., Ltd. In addition, examples of the hard coat TAC film include trade name: CHC manufactured by TOPPAN TOMOEGAWA Optical Films Co., Ltd.

The glass substrate-anti-glare layer can be obtained by providing an anti-glare layer by subjecting the main surface of the glass substrate having the anti-reflective film to an anti-glare treatment.

A method of the anti-glare treatment is not particularly limited, and a method of subjecting, for example, the main surface of the glass substrate to a surface treatment to form desired irregularities can be used.

Specifically, a method of chemically treating the main surface of the glass substrate, for example, a method of applying a frost treatment, can be used. In the frost treatment, for example, a glass substrate to be treated is immersed in a mixed solution containing hydrogen fluoride and ammonium fluoride, and the immersed surface can be subjected to a chemical surface treatment.

In addition to chemical treatment methods such as a frost treatment, for example, a method by a physical treatment can also be used including a so-called sandblast treatment in which a crystalline silicon dioxide powder, a silicon carbide powder, or the like is blown onto the surface of the glass substrate with pressurized air, and a method of polishing with a brush to which a crystalline silicon dioxide powder, a silicon carbide powder or the like adheres is moistened with water.

Examples of the glass substrate-anti-glare layer include trade name: AG process manufactured by NSC Co., Ltd.

### <Anti-Reflective Film>

The anti-reflective film in the present embodiment has a light absorption ability. Here, the anti-reflective film “having a light absorption ability” means that the anti-reflective film has a luminous transmittance of 90% or less as measured by a method described in Examples to be described later. That is, an anti-reflective film is provided on a transparent substrate such as a glass substrate, and the luminous transmittance is measured using a spectrophotometer according to the provisions in JIS Z 8709 (1999).

In the present embodiment, since the anti-reflective film having a light absorption ability is disposed at a position closer to the surface into which external light enters in the self-luminous display device, the light reflected by the anti-reflective film, the transparent substrate, or the adhesive layer can be absorbed efficiently. Accordingly, a display contrast is increased, and the visibility is excellent.

The luminous transmittance of the anti-reflective film in the present embodiment is preferably 85% or less, and more preferably 80% or less. Examples of a method for setting the light transmittance within the above range include specifying components of a first dielectric layer and a second dielectric layer and adjusting an oxidation rate, as to be described later. From the viewpoint of the luminance of the display, the luminous transmittance is generally 20% or more. Examples of a method for imparting a light absorption ability to the anti-reflective film include specifying the components of the first dielectric layer and the second dielectric layer and adjusting the oxidation rate, as to be described later.

The anti-reflective film in the present embodiment preferably has a laminated structure in which at least two dielectric layers having different refractive indices are laminated, and preferably has a function of preventing light reflection.

The anti-reflective film (multilayer film) 24 shown in FIG. 4 has a laminated structure including two layers in which a first dielectric layer 24a and a second dielectric layer 24b having different refractive indices are laminated. When the first dielectric layer 24a and second dielectric layer 24b having different refractive indices are laminated, the light reflection can be prevented. The first dielectric layer 24a is a high refractive index layer and the second dielectric layer 24b is a low refractive index layer.

In the anti-reflective film (multilayer film) 24 shown in FIG. 4, the first dielectric layer 24a is preferably mainly formed of a mixed oxide of an oxide of at least one selected from the group A consisting of Mo and W and an oxide of at least one selected from the group B consisting of Si, Nb, Ti, Zr, Ta, Al, Sn, and In.

In the mixed oxide, a content of elements of the group B contained in the mixed oxide (hereinafter, referred to as a group B content) is preferably 65 mass % or less with respect to a total of elements of the group A contained in the mixed oxide and the elements in the group B contained in the mixed oxide. Here, “mainly” means a component that is contained in the largest amount (in terms of mass) in the first dielectric layer 24a, and means that the first dielectric layer 24a contains, for example, 70 mass % or more of the component.

When the group B content in the first dielectric layer (A-B-O) 24a, which is formed of the mixed oxide of an oxide of at least one selected from the group A consisting of Mo and W and an oxide of at least one selected from the group B consisting of Si, Nb, Ti, Zr, Ta, Al, Sn, and In, is 65 mas % or less, it is possible to prevent the transmitted light from being yellowish.

The second dielectric layer 24b is preferably mainly formed of an oxide of Si (SiOₓ). Here, “mainly” means a component that is contained in the largest amount (in terms of mass) in the second dielectric layer 24b, and means that the second dielectric layer 24b contains, for example, 70 mass % or more of the component.

The first dielectric layer 24a is preferably formed of the mixed oxide of an oxide of at least one selected from the group A consisting of Mo and W and an oxide of at least one selected from the group B consisting of Si, Nb, Ti, Zr, Ta, Al, Sn, and In. Among them, Mo in the group A is preferred, and Nb in the group B is preferred.

It is more preferable that the second dielectric layer 24b be an oxygen-deficient silicon oxide layer and the first dielectric layer 24a include Mo and Nb since, by using Mo and Nb, the silicon oxide layer is not yellowish even when oxygen is deficient, whereas the oxygen-deficient silicon oxide layer in the related art is yellowish under visible light.

The first dielectric layer 24a has a refractive index at a wavelength of 550 nm of preferably 1.8 to 2.3 from the viewpoint of a transmittance with the transparent substrate.

The first dielectric layer 24a has an extinction coefficient of preferably 0.005 to 3, and more preferably 0.04 to 0.38. When the extinction coefficient is 0.005 or more, a desired absorption rate can be achieved with an appropriate number of layers. In addition, when the extinction coefficient is 3 or less, it is relatively easy to achieve both the reflection color and the transmittance.

The anti-reflective film (multilayer film) 24 shown in FIG. 4 has a two-layer laminated structure in which the first dielectric layer 24a and the second dielectric layer 24b are laminated. The anti-reflective film (multilayer film) in the present embodiment is not limited to this, and may have a laminated structure in which three or more dielectric layers having different refractive indices are laminated. In this case, it is not necessary for all dielectric layers to have different refractive indices. For example, in the case of a three-layer laminated structure, it can be a three-layer laminated structure including a low refractive index layer, a high refractive index layer, and a low refractive index layer, or a three-layer laminated structure including a high refractive index layer, a low refractive index layer, and a high refractive index layer. In the former case, the two low refractive index layers may have the same refractive index, and in the latter case, the two high refractive index layers may have the same refractive index. In addition, for example, in the case of a four-layer laminated structure, it can be a four-layer laminated structure including a low refractive index layer, a high refractive index layer, a low refractive index layer, and a high refractive index layer, or a four-layer laminated structure including a high refractive index layer, a low refractive index layer, a high refractive index layer, and a low refractive index layer. In this case, the two low refractive index layers or the two high refractive index layers may independently have the same refractive index.

In the case of a laminated structure in which three or more layers having different refractive indices are laminated, a dielectric layer other than the first dielectric layer (A-B-O) 24a and the second dielectric layer (SiOₓ) 24b may be included. In this case, each layer is selected to form a three-layer laminated structure including a low refractive index layer, a high refractive index layer, and a low refractive index layer, or a three-layer laminated structure including a high refractive index layer, a low refractive index layer, and a high refractive index layer, or a four-layer laminated structure including a low refractive index layer, a high refractive index layer, a low refractive index layer, and a high refractive index layer, or a four-layer laminated structure including a high refractive index layer, a low refractive index layer, a high refractive index layer, and a low refractive index layer, each laminated structure including the first dielectric layer (A-B-O) 24a and the second dielectric layer (SiOₓ) 24b.

The outermost layer is preferably the second dielectric layer (SiOₓ) 24b. When the outermost layer is the second dielectric layer (SiOₓ) 24b in order to obtain low reflectivity, production is relatively easy. In addition, in the case of forming an antifouling film to be described later on the anti-reflective film 24, it is preferable to form the antifouling film on the second dielectric layer (SiOₓ) 24b from the viewpoint of bonding properties related to the durability of the antifouling film.

The first dielectric layer (A-B-O) 24a is preferably amorphous. Being amorphous, it can be produced at a relatively low temperature, and is suitable for use in the case where the transparent substrate includes a resin, since the resin is not damaged by heat.

Note that a halftone mask for use in the semiconductor production field is known as a light transmitting film having a light absorption ability and an insulating property. As the halftone mask, an oxygen-deficient film such as a Mo—SiOₓ film containing a small amount of Mo is used. In addition, as the light transmitting film having a light absorption ability and an insulating property, a narrow bandgap film for use in the semiconductor production field is known.

However, these light transmitting films have a high light absorption ability on the short wavelength side of visible light, so that the transmitted light is yellowish. Therefore, it is not suitable for application to a self-luminous display device.

In a preferred embodiment of the present invention, when the first dielectric layer 24a has a high content of Mo or W and the second dielectric layer 24b is formed of SiOₓ or the like, it is possible to obtain an anti-reflective film-attached transparent substrate having a light absorption ability, an insulating property, and excellent adhesion and strength.

The anti-reflective film 24 in the present embodiment can be formed on the main surface of the transparent substrate using a known film-forming method such as a sputtering method, a vacuum deposition method, or a coating method. That is, the dielectric layers constituting the anti-reflective film 24 are formed on the main surface of the transparent substrate, the anti-glare layer, the hard coat layer, or the like, according to the lamination order, using a known film-forming method such as a sputtering method, a vacuum deposition method, or a coating method.

In addition, the anti-reflective film 24 may be formed on the main surface of the transparent substrate by combining a plurality of film-forming methods. For example, there is a method in which the anti-reflective film 24 is formed by a sputtering method, and only the antifouling film on the outermost surface is formed by a vapor deposition method or a coating method, or a method in which all layers except the outermost layer of the anti-reflective film 24 are formed by a sputtering method, and only the outermost layer is formed of an organic film having an antifouling property.

Among them, the anti-reflective film 24 is preferably formed by a method of laminating thin films in a vacuum, such as a sputtering method or a vacuum deposition method, from the viewpoint of low reflectivity, high durability, and high hardness. According to such a lamination method in a vacuum, the surface hardness is excellent, the low reflectivity effect is high, the SCI Y value can be stably kept to 1.5% or less, and the in-plane reflectivity distribution is also moderate, compared to forming an anti-reflective film by wet coating, in which a coating liquid is cured and dried.

Examples of the sputtering method include methods such as magnetron sputtering, pulse sputtering, AC sputtering, and digital sputtering.

For example, the magnetron sputtering method is a method in which a magnet is placed on a back surface of a base dielectric material to generate a magnetic field, and gas ion atoms collide with the surface of the dielectric material and are ejected, to form a sputtering film having a thickness of several nm, and a continuous film of a dielectric that is an oxide or a nitride of the dielectric material can be formed.

In addition, for example, the digital sputtering method is a method of forming a metal oxide thin film by repeating steps of first forming a metal ultra-thin film by sputtering, and then oxidizing the film by irradiation with oxygen plasma, oxygen ions, or oxygen radicals in the same chamber, unlike a general magnetron sputtering method. In this case, since film-forming molecules are metals when deposited on a substrate, it is presumed to be more ductile than a case of depositing a metal oxide. Therefore, it is conceivable that even when the energy is the same, rearrangement of the film-forming molecules is likely to occur, and as a result, a dense and smooth film can be formed.

### <Antifouling Film>

The anti-reflective film-attached transparent substrate according to the present embodiment may further include an antifouling film (also referred to as an “anti finger print (AFP) film”) on the anti-reflective film, from the viewpoint of protecting the outermost surface of the anti-reflective film. The antifouling film is formed of, for example, a fluorine-containing organosilicon compound. The fluorine-containing organosilicon compound is not particularly limited as long as it can impart an antifouling property, water repellency, and oil repellency, and examples thereof include a fluorine-containing organosilicon compound having one or more groups selected from the group consisting of a polyfluoropolyether group, a polyfluoroalkylene group, and a polyfluoroalkyl group. Note that the polyfluoropolyether group is a divalent group having a structure in which polyfluoroalkylene groups and etheric oxygen atoms are alternately bonded.

As a commercially available fluorine-containing organosilicon compound having one or more groups selected from the group consisting of a polyfluoropolyether group, a polyfluoroalkylene group, and a polyfluoroalkyl group, KP-801 (trade name, manufactured by Shin-Etsu Chemical Co., Ltd.), KY178 (trade name, manufactured by Shin-Etsu Chemical Co., Ltd.), KY-130 (trade name, manufactured by Shin-Etsu Chemical Co., Ltd.), KY-185 (trade name, manufactured by Shin-Etsu Chemical Co., Ltd.), and Optool (registered trademark) DSX and Optool AES (trade name, all manufactured by Daikin Industries, Ltd.) can be preferably used.

In the case where the anti-reflective film-attached transparent substrate according to the present embodiment includes an antifouling film, the antifouling film is provided on the anti-reflective film. When the anti-reflective film is provided on both main surfaces of the transparent substrate, the antifouling film can be formed on both the anti-reflective films, or the antifouling film may be laminated on only one of the main surfaces. This is because the antifouling film only needs to be provided at places where there is a possibility of contact with human hands, and the configuration can be selected according to the application.

### <Adhesive Layer>

As shown in FIG. 1, the anti-reflective film-attached transparent substrate according to the present embodiment may have the adhesive layer 21 on one of the two main surfaces of the transparent substrate, on which an anti-reflective film, an anti-glare layer, a hard coat layer, or the like is not provided. The anti-reflective film-attached transparent substrate 20 is attached to the self-luminous display 10 via the adhesive layer 21.

The adhesive layer can be formed by using a known adhesive composition that is generally used in self-luminous display devices, and examples thereof include an optical clear adhesive (OCA) and an optical clear resin (OCR) such as a UV curable resin. Examples of the OCA and the OCR include polymers such as an acrylic polymer, a silicone polymer, a polyester, a polyurethane, a polyamide, a polyvinyl ether, a vinyl acetate/vinyl chloride copolymer, a modified polyolefin, and rubbers such as an epoxy rubber, fluorine rubber, a natural rubber, and a synthetic rubber. Particularly, an acrylic polymer is suitably used since it exhibits adhesive properties such as moderate wettability, cohesiveness, and adhesion, is also excellent in transparency, weather resistance, heat resistance, and solvent resistance, and has a wide range of adhesive strength.

The adhesive layer has a luminous transmittance of preferably 90% or more, more preferably 91% or more, and still more preferably 92% or more, as measured using a spectrophotometer according to the provisions in JIS Z 8709 (1999). When the transmittance of the adhesive layer is within the above range, the visibility of the display is not impaired.

### (Luminous Transmittance: Y)

The anti-reflective film-attached transparent substrate included in the self-luminous display device according to the present embodiment preferably has a luminous transmittance (Y) of 20% to 90%. In the case where the luminous transmittance (Y) is within the above range, a moderate light absorption ability can be obtained, so that in the case where the anti-reflective film-attached transparent substrate is used in a self-luminous display device, glare of external light can be prevented. Accordingly, a bright contrast and a dark contrast of the self-luminous display device are increased. The luminous transmittance (Y) is more preferably 50% to 90%, and still more preferably 60% to 90%.

The luminous transmittance (Y) may be 88% or less, 80% or less, 75% or less, or 70% or less, and may be 30% or more, or 40% or more.

Note that, the luminous transmittance (Y) can be measured according to the method specified in JIS Z 8709 (1999), as to be described later in Examples. Specifically, a spectral transmittance of the anti-reflective film-attached transparent substrate is measured using a spectrophotometer (trade name: Solid Spec-3700, manufactured by Shimadzu Corporation), and the luminous transmittance (Y) is determined by calculation.

In order to set the luminous transmittance (Y) to 20% to 90% in the anti-reflective film-attached transparent substrate included in the self-luminous display device according to the present embodiment, for example, adjustment can be made by controlling an irradiation time, an irradiation output, and a distance from the substrate for the oxidation source, and an amount of oxidation gas during film-formation of the first dielectric layer in the anti-reflective film, which is a high refractive index layer. Specifically, for example, as the second dielectric layer, it is preferable to mainly use a mixed oxide of an oxide of at least one selected from the group A consisting of Mo and W and an oxide of at least one selected from the group B consisting of Si, Nb, Ti, Zr, Ta, Al, Sn, and In, and to adjust an amount of oxidation of the film.

### (Luminous Reflectance: SCI Y)

In the anti-reflective film-attached transparent substrate included in the self-luminous display device according to the present embodiment, a luminous reflectance (SCI Y) on the outermost surface of the anti-reflective film-attached transparent substrate is preferably 1.5% or less. When the luminous reflectance (SCI Y) is within the above range, in the case where the anti-reflective film-attached transparent substrate is used in an image display device, an effect of preventing glare of external light on a screen is high. The luminous reflectance (SCI Y) is more preferably 1% or less, still more preferably 0.9% or less, even more preferably 0.8% or less, and particularly preferably 0.75% or less.

Note that, the luminous reflectance (SCI Y) can be measured using a spectrophotometer (trade name: CM-26d, manufactured by Konica Minolta, Inc.) according to the method specified in JIS Z 8722 (2009), as to be described later in Examples. Specifically, an OLED panel is attached to the anti-reflective film-attached transparent substrate via an adhesive layer using a hand roller, and in this state, the light is turned off and the luminous reflectance (SCI Y) can be measured using a spectrophotometer.

In order to set the luminous reflectance (SCI Y) to 1.5% or less in the anti-reflective film-attached transparent substrate included in the self-luminous display device according to the present embodiment, for example, the luminous transmittance (Y) of the anti-reflective film-attached transparent substrate is set to 90% or less. For this purpose, for example, as the first dielectric layer, it is preferable to mainly use a mixed oxide of an oxide of at least one selected from the group A consisting of Mo and W and an oxide of at least one selected from the group B consisting of Si, Nb, Ti, Zr, Ta, Al, Sn, and In, and to adjust an amount of oxidation of the film. By adjusting the amount of oxidation to provide absorption to the anti-reflective film, it is possible to prevent diffuse reflection from an anti-glare layer or the like formed on the transparent substrate.

### (Diffuse Reflectance: SCE Y)

In the anti-reflective film-attached transparent substrate included in the self-luminous display device according to the present embodiment, a diffuse reflectance (SCE Y) on the outermost surface of the anti-reflective film-attached transparent substrate is preferably 0.05% or more, more preferably 0.1% or more, and still more preferably 0.2% or more. The diffuse reflectance (SCE Y) is preferably within the above range since in the case where the anti-reflective film-attached transparent substrate is used in an image display device, the effect of preventing glare of external light on a screen is higher.

The diffuse reflectance (SCE Y) can be measured using a spectrophotometer (trade name: CM-26d, manufactured by Konica Minolta, Inc.) according to the method specified in JIS Z 8722 (2009), as to be described later in Examples. Specifically, an OLED panel is attached to the anti-reflective film-attached transparent substrate via an adhesive layer using a hand roller, and in this state, the light is turned off and the diffuse reflectance (SCE Y) is measured using a spectrophotometer.

In order to set the diffuse reflectance (SCE Y) to 0.05% or more in the anti-reflective film-attached transparent substrate included in the self-luminous display device according to the present embodiment, for example, a haze value of the anti-reflective film-attached transparent substrate to be described later is set to 10% or more.

### (Diffuse Reflectance: SCE Y/Luminous Reflectance: SCI Y)

In the anti-reflective film-attached transparent substrate included in the self-luminous display device according to the present embodiment, a ratio of the diffuse reflectance (SCE Y) on the outermost surface of the anti-reflective film-attached transparent substrate to the luminous reflectance (SCI Y) on the outermost surface of the anti-reflective film-attached transparent substrate, SCE Y/SCI Y, is preferably 0.15 or more.

The luminous reflectance (SCI Y) is a value measured for total reflected light, including specular reflected light and diffuse reflected light, and is thus an evaluation of the color of the material per se, regardless of the surface state of the anti-reflective film-attached transparent substrate. On the other hand, the diffuse reflectance (SCE Y) is a value measured for only the diffuse reflected light, excluding the specular reflected light in the total reflected light, and is thus an evaluation of a color that is close to what is visually observed.

Therefore, when the ratio of the diffuse reflectance (SCE Y) to the luminous reflectance (SCI Y) is high, this means the ratio of the diffuse reflected light to the total reflected light (specular reflected light+diffuse reflected light) is high, and the glare of the external light on a screen is reduced, which is preferable.

The SCE Y/SCI Y is preferably 0.2 or more, more preferably 0.25 or more, still more preferably 0.3 or more, even more preferably 0.35 or more, even still more preferably 0.4 or more, further still more preferably 0.45 or more, further even more preferably 0.5 or more, and particularly preferably 0.6 or more. In addition, the SCE Y/SCI Y may be, for example, 1 or less, or 0.75 or less.

In order to set the SCE Y/SCI Y to 0.15 or more in the anti-reflective film-attached transparent substrate according to the present embodiment, for example, it is preferable to use a transparent substrate having a haze value of 1% or more, more preferably to use a transparent substrate having a haze value of 10% or more, still more preferably to use a transparent substrate having a haze value of 15% or more, and particularly preferably to use a transparent substrate having a haze value of 20% or more.

### (b* Value in Transmission Color Under D65 Light Source)

In the anti-reflective film-attached transparent substrate included in the self-luminous display device according to the present embodiment, a b* value in a transmission color under a D65 light source is preferably 5 or less. When the b* value is within the above range, the transmitted light is not yellowish, so that the anti-reflective film-attached transparent substrate is suitably used in a self-luminous display device. The b* value is more preferably 3 or less, and still more preferably 2 or less. In addition, the b* value has a lower limit value of preferably −6 or more, and more preferably −4 or more. The b* value is preferably within the above range since the transmitted light is colorless and the transmitted light is not hindered.

Note that the b* value in a transmission color under a D65 light source can be measured according to the method specified in JIS Z 8729 (2004), as to be described later in Examples.

In order to set the b* value in a transmission color under a D65 light source to 5 or less in the anti-reflective film-attached transparent substrate included in the self-luminous display device according to the present embodiment, for example, the material composition of the first dielectric layer is adjusted. Specifically, when the proportion of the group A is increased, the transmittance of a short wavelength increases, and a decrease in b* value can be expected.

### (Haze Value)

The haze value of the anti-reflective film-attached transparent substrate included in the self-luminous display device according to the present embodiment can be set appropriately and may be, for example, 1% or more, 10% or more, 15% or more, or 20% or more. When the haze value is within the above range, the glare of the external light can be more effectively prevented.

The haze value is measured according to JIS K 7136:2000 using a haze meter (HR-100 model, manufactured by MURAKAMI COLOR RESEARCH LABORATORY CO., LTD.) or the like.

### (Sa)

The anti-reflective film-attached transparent substrate included in the self-luminous display device according to the present embodiment has an arithmetic mean surface roughness (Sa) of preferably 0.05 μm to 0.6 μm, and more preferably 0.05 μm to 0.55 μm. The Sa is specified in ISO25178, and can be measured, for example, using a laser microscope VK-X3000 manufactured by Keyence Corporation.

A small Sa means that irregularities on the outermost surface of the transparent substrate are small, and the diffusibility of the reflected light is low, whereby the diffuse reflectance (SCE Y) is reduced, and the effect of preventing glare is difficult to obtain. A large Sa means that the surface irregularities are large, the diffuse reflectance is increased, but surface dirt is difficult to remove, making it not preferred as a display surface material. The Sa can be adjusted by appropriately changing parameters such as the kind and an average particle diameter of fine particles used as a diffusion material, and the mixed amount thereof, appropriately controlling etching conditions in a surface treatment, or appropriately curing and forming an unbalanced anti-glare layer such as a sol-gel silica system.

### (Sdr)

In the anti-reflective film-attached transparent substrate included in the self-luminous display device according to the present embodiment, a developed area ratio Sdr (hereinafter, simply referred to as “Sdr”) calculated based on the surface area obtained by measurement using a laser microscope such as VK-X3000 manufactured by Keyence Corporation is preferably 0.001 to 0.12, and more preferably 0.0025 to 0.11.

A small Sdr means that the surface area of the transparent substrate is small, and when the surface area decreases relatively, the diffusibility of the reflected light is low, the diffuse reflectance (SCE Y) is reduced, and the effect of preventing glare is difficult to obtain. A large Sdr means that the surface area of the transparent substrate is large, and the area of the anti-reflective layer exposed to the outside air increases relatively, so that there is a growing concern that the reliability of the anti-reflective film may decrease. The Sdr can be adjusted by appropriately changing parameters such as the kind and an average particle diameter of fine particles used as a diffusion material, and the mixed amount thereof, appropriately controlling etching conditions in a surface treatment, or appropriately curing and forming an unbalanced anti-glare layer such as a sol-gel silica system.

The Sdr is specified in ISO25178 and is expressed by the following equation.

$$Developed area ratio Sdr = \{ ( A - B ) / B \}$$

$$A : surface area ( developed area ) reflecting actual irregularities in measurement region$$

$$B : area of flat surface without any irregularities in measurement region ( Sdq )$$

The anti-reflective film-attached transparent substrate included in the self-luminous display device according to the present embodiment has a root mean square slope (Sdq) of preferably 0.03 μm to 0.50 μm, and more preferably 0.07 μm to 0.49 μm. The Sdq is specified in ISO25178, and can be measured, for example, using a laser microscope VK-X3000 manufactured by Keyence Corporation.

A small Sdq means that the root mean square slope is small, and the diffusibility of the reflected light is low, whereby the diffuse reflectance (SCE Y) is reduced, and the effect of preventing glare is difficult to obtain. A large Sdq means that the root mean square slope is large, and the sharpness of the outermost surface of the transparent substrate increases, whereby it feels like something is catching when the device is touched with fingers or cloth, and the sense of touch deteriorates. The Sdq can be adjusted by appropriately changing parameters such as the kind and an average particle diameter of fine particles used as a diffusion material, and the mixed amount thereof, appropriately controlling etching conditions in a surface treatment, or appropriately curing and forming an unbalanced anti-glare layer such as a sol-gel silica system.

### (Spc)

The anti-reflective film-attached transparent substrate included in the self-luminous display device according to the present embodiment has an average principal curvature of surface peaks (Spc) of preferably 150 to 2500 (1/mm). The Spc is specified in ISO25178, and can be measured, for example, using a laser microscope VK-X3000 manufactured by Keyence Corporation.

A small Spc means that the arithmetic mean curvature of the peak is small, the diffuse reflectance (SCE Y) on the outermost surface of the transparent substrate is reduced, and the effect of preventing glare cannot be obtained. A large Spc means that the arithmetic mean curvature of the peak is large, and it feels like something is catching when the device is touched with fingers or cloth, and the sense of touch deteriorates. The Spc can be adjusted by appropriately changing parameters such as the kind and an average particle diameter of fine particles used as a diffusion material, and the mixed amount thereof, appropriately controlling etching conditions in a surface treatment, or appropriately curing and forming an unbalanced anti-glare layer such as a sol-gel silica system.

### (Sheet Resistance)

In the anti-reflective film-attached transparent substrate included in the self-luminous display device according to the present embodiment, the anti-reflective film preferably has a sheet resistance of 10⁴Ω/□ or more. When the sheet resistance of the anti-reflective film is within the above range, the anti-reflective film has an insulating property. Therefore, in the case where the anti-reflective film-attached transparent substrate is used as a self-luminous display device, even when a touch panel is provided, a change in capacitance due to finger contact, which is necessary for a capacitive touch sensor, is maintained, and the touch panel can function. The sheet resistance is more preferably 10⁶Ω/□ or more, and still more preferably 10⁸Ω/□ or more.

Note that the sheet resistance can be measured according to the method specified in JIS K 6911 (2006). Specifically, measurement can be performed by placing a probe at a center of the anti-reflective film-attached transparent substrate and applying a current under 10 V for 10 seconds.

In order to set the sheet resistance of the anti-reflective film to 10⁴Ω/□ or more in the anti-reflective film-attached transparent substrate included in the self-luminous display device according to the present embodiment, for example, the metal content in the anti-reflective film is adjusted.

### (Diffuse Reflected Light Brightness: SCE L*)

In the anti-reflective film-attached transparent substrate included in the self-luminous display device according to the present embodiment, a diffuse reflected light brightness (SCE L*) is preferably 7 or less. The diffuse reflected light brightness (SCE L*) is preferably within the above range since in the case where the anti-reflective film-attached transparent substrate is used in a self-luminous display device, the effect of preventing glare of external light on a screen is higher. The diffuse reflected light brightness (SCE L*) is more preferably 6 or less, and still more preferably 5 or less.

Note that, the diffuse reflected light brightness (SCE L*) can be measured using a spectrophotometer (trade name: CM-26d, manufactured by Konica Minolta, Inc.) according to the method specified in JIS Z 8722 (2009), as to be described later in Examples. Specifically, an OLED panel is attached to the anti-reflective film-attached transparent substrate via an adhesive layer using a hand roller, and in this state, the light is turned off and the diffuse reflected light brightness (SCE L*) can be measured using a spectrophotometer.

In order to set the diffuse reflected light brightness (SCE L*) to 7 or less in the anti-reflective film-attached transparent substrate included in the self-luminous display device according to the present embodiment, for example, the haze value of the anti-reflective film-attached transparent substrate is reduced.

### (Diffuse Reflected Light Chromaticity: SCE a* and SCE b*)

In the anti-reflective film-attached transparent substrate included in the self-luminous display device according to the present embodiment, a diffuse reflected light chromaticity (SCE a*) is preferably −5 to 5. The diffuse reflected light chromaticity (SCE a*) is preferably within the above range since in the case where the anti-reflective film-attached transparent substrate is used in a self-luminous display device, the color reproducibility of the display device is higher. The diffuse reflected light chromaticity (SCE a*) is more preferably −5 to 5, and still more preferably −4 to 4.5.

In the anti-reflective film-attached transparent substrate included in the self-luminous display device according to the present embodiment, a diffuse reflected light chromaticity (SCE b*) is preferably −8 to 5. The diffuse reflected light chromaticity (SCE b*) is preferably within the above range since in the case where the anti-reflective film-attached transparent substrate is used in a self-luminous display device, the color reproducibility of the display device is higher. The diffuse reflected light chromaticity (SCE b*) is more preferably −7 to 4, and still more preferably −6 to 4.

Note that, the diffuse reflected light chromaticity (SCE a* and SCE b*) can be measured using a spectrophotometer (trade name: CM-26d, manufactured by Konica Minolta, Inc.) according to the method specified in JIS Z 8722 (2009), as to be described later in Examples. Specifically, an OLED panel is attached to the anti-reflective film-attached transparent substrate via an adhesive layer using a hand roller, and in this state, the light is turned off and the diffuse reflected light chromaticity (SCE a* and SCE b*) can be measured using a spectrophotometer.

### (Total Reflected Light Brightness: SCI L*)

In the anti-reflective film-attached transparent substrate included in the self-luminous display device according to the present embodiment, a total reflected light brightness (SCI L*) is preferably 9 or less. The total reflected light brightness (SCI L*) is preferably within the above range since in the case where the anti-reflective film-attached transparent substrate is used in a self-luminous display device, the effect of preventing glare of external light on a screen is higher. The total reflected light brightness (SCI L*) is more preferably 8 or less, and still more preferably 6 or less.

Note that, the total reflected light brightness (SCI L*) can be measured using a spectrophotometer (trade name: CM-26d, manufactured by Konica Minolta, Inc.) according to the method specified in JIS Z 8722 (2009), as to be described later in Examples. Specifically, an OLED panel is attached to the anti-reflective film-attached transparent substrate via an adhesive layer using a hand roller, and in this state, the light is turned off and the total reflected light brightness (SCI L*) can be measured using a spectrophotometer.

In order to set the total reflected light brightness (SCI L*) to 9 or less in the anti-reflective film-attached transparent substrate included in the self-luminous display device according to the present embodiment, for example, the haze value of the anti-reflective film-attached transparent substrate is reduced, or the luminous transmittance (Y) of the anti-reflective film-attached transparent substrate is set to 90% or less.

### (Total Reflected Light Chromaticity: SCI a* and SCI b*)

In the anti-reflective film-attached transparent substrate included in the self-luminous display device according to the present embodiment, a total reflected light chromaticity (SCI a*) is preferably −5 to 5. The total reflected light chromaticity (SCI a*) is preferably within the above range since in the case where the anti-reflective film-attached transparent substrate is used in a self-luminous display device, the color reproducibility of the display device is higher. The total reflected light chromaticity (SCI a*) is more preferably −3 to 3, and still more preferably −2 to 2.

In the anti-reflective film-attached transparent substrate included in the self-luminous display device according to the present embodiment, a total reflected light chromaticity (SCI b*) is preferably −6 to 6. The total reflected light chromaticity (SCI b*) is preferably within the above range since in the case where the anti-reflective film-attached transparent substrate is used in a self-luminous display device, the color reproducibility of the display device is higher. The total reflected light chromaticity (SCI b*) is more preferably −4 to 4, and still more preferably −3 to 3.

Note that, the total reflected light chromaticity (SCI a* and SCI b*) can be measured using a spectrophotometer (trade name: CM-26d, manufactured by Konica Minolta, Inc.) according to the method specified in JIS Z 8722 (2009), as to be described later in Examples. Specifically, an OLED panel is attached to the anti-reflective film-attached transparent substrate via an adhesive layer using a hand roller, and in this state, the light is turned off and the total reflected light chromaticity (SCI a* and SCI b*) can be measured using a spectrophotometer.

### (Bright Contrast)

The anti-reflective film-attached transparent substrate included in the self-luminous display device according to the present embodiment has a high bright contrast as shown by the following equation. As to be described later in Examples, the bright contrast is determined by attaching an OLED panel to the anti-reflective film-attached transparent substrate via an adhesive layer using a hand roller, measuring the luminance in a white display and the luminance in a black display using a two-dimensional color luminance meter (CA-2000 manufactured by Konica Minolta, Inc.) in an environment of 300 lux (corresponding to the brightness in an indoor room), and calculating the bright contrast according to the following equation. Note that, the white display and the black display refer to a state where the display device is turned on and displays a white screen or a black screen.

$$Bright contrast = luminance in white display / luminance in black display$$

### (Dark Contrast)

The anti-reflective film-attached transparent substrate included in the self-luminous display device according to the present embodiment also has a high dark contrast as shown by the following equation. As to be described later in Examples, the dark contrast is determined by attaching an OLED panel to the anti-reflective film-attached transparent substrate via an adhesive layer using a hand roller, measuring the luminance in a white display and the luminance in a black display using a two-dimensional color luminance meter (CA-2000 manufactured by Konica Minolta, Inc.) in a dark room (0 lux), and calculating the dark contrast according to the following equation.

$$Dark contrast = luminance in white display / luminance in black display$$

### EXAMPLES

Hereinafter, the present invention is described in detail with reference to Examples, but the present invention is not limited thereto. Examples 1 to 10 are Inventive Examples, and Examples 11 to 14 are Comparative Examples.

### Example 1

An anti-reflective film-attached transparent substrate in Example 1 was prepared by the following method.

A hard coat TAC film (trade name: CHC manufactured by TOPPAN TOMOEGAWA Optical Films Co., Ltd.) including a hard coat (HC) layer on a transparent substrate was prepared, and in surfaces thereof, a main surface on which the hard coat layer was not provided was coated with a transparent adhesive (acrylic adhesive “TD06A” manufactured by TOMOEGAWA CORPORATION), to form an adhesive layer having a thickness of 10 μm. That is, a laminate including an adhesive layer, a transparent substrate, and a hard coat layer was prepared.

Next, an anti-reflective film (dielectric layer) was formed on the hard coat layer as follows.

First, as a dielectric layer (1) (high refractive index layer), in a digital sputtering method, a target obtained by mixing and sintering niobium and molybdenum in a weight ratio of 50:50 was used, the pressure was kept at 0.2 Pa with an argon gas, pulse sputtering was performed under conditions of a frequency of 100 kHz, a power density of 10.0 W/cm², and a reverse pulse width of 3 μsec to form a metal film having a minute thickness, and immediately thereafter, oxidation with an oxygen gas was performed. This process was repeated at a high speed to form an oxide film, and a Mo-Nb—O layer having a thickness of 20 nm was formed on the main surface of the hard coat layer. Note that, it was found that the Mo—Nb—O layer contained Mo and Nb elements in a total amount of 70 mass % or more.

Here, an oxygen flow rate during the oxidation with an oxygen gas was 800 sccm, and an input power of an oxidation source was 1000 W.

Next, as a dielectric layer (2) (low refractive index layer), in the same digital sputtering method, a silicon target was used, the pressure was kept at 0.2 Pa with an argon gas, pulse sputtering was performed under conditions of a frequency of 100 kHz, a power density of 10.0 W/cm², and a reverse pulse width of 3 μsec to form a silicon film having a minute thickness, and immediately thereafter, oxidation with an oxygen gas was performed. This process was repeated at a high speed to form a silicon oxide film, and a layer including a silicon oxide (silica (SiOₓ)) having a laminated thickness of 30 nm was formed on the Mo—Nb—O layer. Here, an oxygen flow rate during the oxidation with an oxygen gas was 500 sccm, and an input power of an oxidation source was 1000 W.

Next, as a dielectric layer (3) (high refractive index layer), in the same digital sputtering method, a target obtained by mixing and sintering niobium and molybdenum in a weight ratio of 50:50 was used, the pressure was kept at 0.2 Pa with an argon gas, pulse sputtering was performed under conditions of a frequency of 100 kHz, a power density of 10.0 W/cm², and a reverse pulse width of 3 μsec to form a metal film having a minute thickness, and immediately thereafter, oxidation with an oxygen gas was performed. This process was repeated at a high speed to form an oxide film, and a Mo—Nb—O layer having a laminated thickness of 120 nm was formed on the silicon oxide layer. Note that, it was found that the Mo—Nb—O layer contained Mo and Nb elements in a total amount of 70 mass % or more.

Here, an oxygen flow rate during the oxidation with an oxygen gas was 800 sccm, and an input power of an oxidation source was 1000 W.

Next, as a dielectric layer (4) (low refractive index layer), in the same digital sputtering method, a silicon target was used, the pressure was kept at 0.2 Pa with an argon gas, pulse sputtering was performed under conditions of a frequency of 100 kHz, a power density of 10.0 W/cm², and a reverse pulse width of 3 μsec to form a silicon film having a minute thickness, and immediately thereafter, oxidation with an oxygen gas was performed. This process was repeated at a high speed to form a silicon oxide film, and a layer including a silicon oxide (silica (SiOₓ)) having a laminated thickness of 88 nm was formed on the Mo—Nb—O layer. Here, an oxygen flow rate during the oxidation with an oxygen gas was 500 sccm, and an input power of an oxidation source was 1000 W.

With the above, an anti-reflective film was provided on the hard coat layer, to obtain an anti-reflective film-attached transparent substrate having an adhesive layer.

The prepared anti-reflective film-attached transparent substrate having an adhesive layer was evaluated as follows. The evaluation results are shown in Table 1.

### (Luminous Transmittance of Anti-reflective Film)

The luminous transmittance of the anti-reflective film was measured using a spectrophotometer (trade name: Solid Spec-3700, manufactured by Shimadzu Corporation) according to JIS Z 8709 (1999) by providing an anti-reflective film same as that formed in the anti-reflective film-attached transparent substrate on one main surface of a chemically strengthened glass substrate (Dragontrail (registered trademark), manufactured by AGC Inc.) having 50 mm in length, 50 mm in width, and 1.1 mm in thickness.

### (Luminous Transmittance of Adhesive Layer)

The luminous transmittance of the adhesive layer was measured using a spectrophotometer (trade name: Solid Spec-3700, manufactured by Shimadzu Corporation) according to JIS Z 8709 (1999) for the adhesive per se before it was attached to the transparent substrate.

### (Haze Value)

The haze value of the anti-reflective film-attached transparent substrate was measured using a haze meter (HR-100 model, manufactured by MURAKAMI COLOR RESEARCH LABORATORY CO., LTD.) according to JIS K 7136:2000.

### (Luminous Transmittance: Y)

In the prepared anti-reflective film-attached transparent substrate, the luminous transmittance (Y) on the outermost surface of the anti-reflective film was measured according to the method specified in JIS Z 8709 (1999). Specifically, a spectral transmittance of the anti-reflective film-attached transparent substrate having an adhesive layer was measured using a spectrophotometer (trade name: Solid Spec-3700, manufactured by Shimadzu Corporation), and the luminous transmittance (Y) was determined by calculation.

### (Transmission Color (b* Value) of Anti-Reflective Film-Attached Transparent Substrate Under D65 Light Source)

The color index (b* value) specified in JIS Z 8729 (2004) was determined based on a transmission spectrum obtained by measuring the above spectral transmittance. As the light source, a D65 light source was used.

### (Luminous Reflectance: SCI Y)

In the prepared anti-reflective film-attached transparent substrate, the luminous reflectance (SCI Y) on the outermost surface of the anti-reflective film-attached transparent substrate was measured according to the method specified in JIS Z 8722 (2009). Specifically, the OLED panel was attached to the anti-reflective film-attached transparent substrate via the adhesive layer using a hand roller, and in this state, the light was turned off and the luminous reflectance (SCI Y) of the total reflected light was measured using a spectrophotometer (trade name: CM-26d, manufactured by Konica Minolta, Inc.). The light source was a D65 light source.

### (Total Reflected Light Brightness: SCI L*)

In the prepared anti-reflective film-attached transparent substrate, the total reflected light brightness (SCI L*) was measured according to the method specified in JIS Z 8722 (2009). Specifically, the OLED panel was attached to the anti-reflective film-attached transparent substrate via the adhesive layer using a hand roller, and in this state, the light was turned off and the total reflected light brightness (SCI L*) was measured using a spectrophotometer (trade name: CM-26d, manufactured by Konica Minolta, Inc.). The light source was a D65 light source.

### (Total Reflected Light Chromaticity: SCI a* and SCI b*)

In the prepared anti-reflective film-attached transparent substrate, the total reflected light chromaticity (SCI a* and SCI b*) was measured according to the method specified in JIS Z 8722 (2009). Specifically, the OLED panel was attached to the anti-reflective film-attached transparent substrate via the adhesive layer using a hand roller, and in this state, the light was turned off and the total reflected light chromaticity (SCI a* and SCI b*) was measured using a spectrophotometer (trade name: CM-26d, manufactured by Konica Minolta, Inc.). The light source was a D65 light source.

### (Diffuse Reflectance: SCE Y)

In the prepared anti-reflective film-attached transparent substrate, the diffuse reflectance (SCE Y) on the outermost surface of the anti-reflective film was measured according to the method specified in JIS Z 8722 (2009). Specifically, the OLED panel was attached to the anti-reflective film-attached transparent substrate via the adhesive layer using a hand roller, and in this state, the light was turned off and the diffuse reflectance (SCE Y) was measured using a spectrophotometer (trade name: CM-26d, manufactured by Konica Minolta, Inc.). The light source was a D65 light source.

### (Diffuse Reflected Light Brightness: SCE L*)

In the prepared anti-reflective film-attached transparent substrate, the diffuse reflected light brightness (SCE L*) was measured according to the method specified in JIS Z 8722 (2009). Specifically, the OLED panel was attached to the anti-reflective film-attached transparent substrate via the adhesive layer using a hand roller, and in this state, the light was turned off and the diffuse reflected light brightness (SCE L*) was measured using a spectrophotometer (trade name: CM-26d, manufactured by Konica Minolta, Inc.). The light source was a D65 light source.

### (Diffuse Reflected Light Chromaticity: SCE a* and SCE b*)

In the prepared anti-reflective film-attached transparent substrate, the diffuse reflected light chromaticity (SCE a* and SCE b*) was measured according to the method specified in JIS Z 8722 (2009). Specifically, the OLED panel was attached to the anti-reflective film-attached transparent substrate via the adhesive layer using a hand roller, and in this state, the light was turned off and the diffuse reflected light chromaticity (SCE a* and SCE b*) was measured using a spectrophotometer (trade name: CM-26d, manufactured by Konica Minolta, Inc.). The light source was a D65 light source.

### (Bright Contrast)

The OLED panel was attached to the anti-reflective film-attached transparent substrate via the adhesive layer using a hand roller, and the luminance in a white display and the luminance in a black display were measured using a two-dimensional color luminance meter (CA-2000 manufactured by Konica Minolta, Inc.) in an environment of 300 lux (corresponding to the brightness in an indoor room) to obtain the bright contrast according to the following equation.

Bright contrast=luminance in white display/luminance in black display

### (Dark Contrast)

The OLED panel was attached to the anti-reflective film-attached transparent substrate via the adhesive layer using a hand roller, and the luminance in a white display and the luminance in a black display were measured using a two-dimensional color luminance meter (CA-2000 manufactured by Konica Minolta, Inc.) in a dark room (0 lux) to obtain the dark contrast according to the following equation.

Dark contrast=luminance in white display/luminance in black display

### (Sheet Resistance)

The sheet resistance value was measured according to JIS K 6911 (2006) using a measuring device (device name: Hiresta UP (MCP-HT450 model) manufactured by Mitsubishi Chemical Analytech Co., Ltd.). Specifically, measurement was performed by placing a probe at a center of the prepared anti-reflective film-attached transparent substrate and applying a current under 10 V for 10 seconds.

### Example 2

A film was formed in the same manner as in Example 1 to obtain an anti-reflective film-attached transparent substrate in Example 2 except that the oxygen flow rate for the high refractive index layer of the anti-reflective film (dielectric layer) was changed to 500 sccm, and the luminous transmittance of the anti-reflective film was changed to 70%. The evaluation results are shown in Table 1 below.

### Example 3

A film was formed in the same manner as in Example 1 to obtain an anti-reflective film-attached transparent substrate in Example 3 except that the oxygen flow rate for the high refractive index layer of the anti-reflective film (dielectric layer) was changed to 500 sccm, the input power was changed to 700 W, and the luminous transmittance of the anti-reflective film was changed to 50%. The evaluation results are shown in Table 1 below.

### Example 4

A film was formed in the same manner as in Example 3 to obtain an anti-reflective film-attached transparent substrate in Example 4 except that the hard coat TAC film was changed to an anti-glare PET film (“EHC-10a” manufactured by Higashiyama Film Co., Ltd.) including an anti-glare layer on a transparent substrate (PET). The evaluation results are shown in Table 1 below.

### Example 5

A film was formed in the same manner as in Example 1 to obtain an anti-reflective film-attached transparent substrate in Example 5 except that the hard coat TAC film was changed to an anti-glare TAC film (“VZ50” manufactured by TOPPAN TOMOEGAWA Optical Films Co., Ltd.) including an anti-glare layer on a transparent substrate (TAC). The evaluation results are shown in Table 1 below.

### Example 6

A film was formed in the same manner as in Example 5 to obtain an anti-reflective film-attached transparent substrate in Example 6 except that the anti-reflective film (dielectric layer) was changed to that in Example 2. The evaluation results are shown in Table 1 below.

### Example 7

A film was formed in the same manner as in Example 5 to obtain an anti-reflective film-attached transparent substrate in Example 7 except that the anti-reflective film (dielectric layer) was changed to that in Example 3. The evaluation results are shown in Table 1 below.

### Example 8

A film was formed in the same manner as in Example 6 to obtain an anti-reflective film-attached transparent substrate in Example 8 except that the hard coat TAC film was changed to an anti-glare PET film (manufactured by REIKO Co., Ltd., haze value: 50%) including an anti-glare layer on a transparent substrate (PET). The evaluation results are shown in Table 2 below.

### Example 9

A film was formed in the same manner as in Example 8 to obtain an anti-reflective film-attached transparent substrate in Example 9 except that the hard coat TAC film was changed to an anti-glare PET film (manufactured by REIKO Co., Ltd., haze value: 60%) including an anti-glare layer on a transparent substrate (PET). The evaluation results are shown in Table 2 below.

### Example 10

A film was formed in the same manner as in Example 7 to obtain an anti-reflective film-attached transparent substrate in Example 10 except that the hard coat TAC film was changed to an anti-glare PET film (manufactured by REIKO Co., Ltd., haze value: 80%) including an anti-glare layer on a transparent substrate (PET). The evaluation results are shown in Table 2 below.

### Example 11

A film was formed in the same manner as in Example 1 to obtain an anti-reflective film-attached transparent substrate in Example 11 except that the adhesive layer was changed to an adhesive layer having a thickness of 25 μm (luminous transmittance: 85%) formed by applying a pigment-containing adhesive (acrylic adhesive “TD06B” manufactured by TOMOEGAWA CORPORATION), and the anti-reflective film (dielectric layer) was changed to a transparent AR film formed by the method described below.

### (Transparent AR Film-Forming Method)

First, as a dielectric layer (1) (high refractive index layer), in a digital sputtering method, a titanium target was used, the pressure was kept at 0.2 Pa with an argon gas, pulse sputtering was performed under conditions of a frequency of 100 kHz, a power density of 10.0 W/cm², and a reverse pulse width of 3 μsec to form a metal film having a minute thickness, and immediately thereafter, oxidation with an oxygen gas was performed. This process was repeated at a high speed to form an oxide film, and a Ti—O layer having a thickness of 11 nm was formed on the main surface of the hard coat layer.

Next, as a dielectric layer (2) (low refractive index layer), in the same digital sputtering method, a silicon target was used, the pressure was kept at 0.2 Pa with an argon gas, pulse sputtering was performed under conditions of a frequency of 100 kHz, a power density of 10.0 W/cm², and a reverse pulse width of 3 μsec to form a silicon film having a minute thickness, and immediately thereafter, oxidation with an oxygen gas was performed. This process was repeated at a high speed to form a silicon oxide film, and a layer including a silicon oxide (silica (SiOₓ)) having a laminated thickness of 35 nm was formed on the Ti—O layer. Here, an oxygen flow rate during the oxidation with an oxygen gas was 500 sccm, and an input power of an oxidation source was 1000 W.

Next, as a dielectric layer (3) (high refractive index layer), in the same digital sputtering method, a titanium target was used, the pressure was kept at 0.2 Pa with an argon gas, pulse sputtering was performed under conditions of a frequency of 100 kHz, a power density of 10.0 W/cm², and a reverse pulse width of 3 μsec to form a metal film having a minute thickness, and immediately thereafter, oxidation with an oxygen gas was performed. This process was repeated at a high speed to form an oxide film, and a Ti—O layer having a laminated thickness of 104 nm was formed on the silicon oxide layer.

Next, as a dielectric layer (4) (low refractive index layer), in the same digital sputtering method, a silicon target was used the pressure was kept at 0.2 Pa with an argon gas, pulse sputtering was performed under conditions of a frequency of 100 kHz, a power density of 10.0 W/cm², and a reverse pulse width of 3 μsec to form a silicon film having a minute thickness, and immediately thereafter, oxidation with an oxygen gas was performed. This process was repeated at a high speed to form a silicon oxide film, and a layer including a silicon oxide (silica (SiOₓ)) having a laminated thickness of 86 nm was formed on the Ti—O layer. Here, an oxygen flow rate during the oxidation with an oxygen gas was 500 sccm, and an input power of an oxidation source was 1000 W.

The evaluation results are shown in Table 2 below.

### Example 12

A film was formed in the same manner as in Example 11 to obtain an anti-reflective film-attached transparent substrate in Example 12 except that the adhesive layer was changed to an adhesive layer having a thickness of 25 μm (luminous transmittance: 70%) formed by applying a pigment-containing adhesive (acrylic adhesive “TD06B” manufactured by TOMOEGAWA CORPORATION). The evaluation results are shown in Table 2 below. Note that, the haze value includes the haze caused by the pigment (scattering component) in the adhesive.

### Example 13

A film was formed in the same manner as in Example 11 to obtain an anti-reflective film-attached transparent substrate in Example 13 except that the adhesive layer was changed to an adhesive layer having a thickness of 25 μm (luminous transmittance: 50%) formed by applying a pigment-containing adhesive (acrylic adhesive “TD06B” manufactured by TOMOEGAWA CORPORATION). The evaluation results are shown in Table 2 below. Note that, the haze value includes the haze caused by the pigment (scattering component) in the adhesive.

### Example 14

A film was formed in the same manner as in Example 11 to obtain an anti-reflective film-attached transparent substrate in Example 14 except that the adhesive layer was changed to an adhesive layer having a thickness of 25 μm (luminous transmittance: 70%) formed by applying a pigment-containing adhesive (acrylic adhesive “TD06B” manufactured by TOMOEGAWA CORPORATION), and the hard coat TAC film was changed to an anti-glare PET film (manufactured by REIKO Co., Ltd., haze value: 50%) including an anti-glare layer on a transparent substrate (PET). The evaluation results are shown in Table 2 below. Note that, the haze value includes the haze caused by the pigment (scattering component) in the adhesive.

TABLE 1

| | | Example 1 | Example 2 | Example 3 | Example 4 | Example 5 | Example 6 | Example 7 |
|---|---|---|---|---|---|---|---|---|
| Anti- | Kind | Absorption | Absorption | Absorption | Absorption | Absorption | Absorption | Absorption |
| reflective | | AR | AR | AR | AR | AR | AR | AR |
| film | Luminous | 85 | 70 | 50 | 50 | 85 | 70 | 50 |
| | transmittance | | | | | | | |
| | (%) | | | | | | | |
| Transparent | Kind | TAC-HC | TAC-HC | TAC-HC | PET-AG | TAC-AG | TAC-AG | TAC-AG |
| substrate | Product | CHC | CHC | CHC | EHC-10a | VZ50 | VZ50 | VZ50 |
| AG layer | name | | | | | | | |
| HC layer | | | | | | | | |
| Adhesive | Kind | Transparent | Transparent | Transparent | Transparent | Transparent | Transparent | Transparent |
| layer | Product | TD06A | TD06A | TD06A | TD06A | TD06A | TD06A | TD06A |
| | name | | | | | | | |
| | Luminous | 93 | 93 | 93 | 93 | 93 | 93 | 93 |
| | transmittance | | | | | | | |
| | (%) | | | | | | | |

| | | | | | | | |
|---|---|---|---|---|---|---|---|
| Haze (%) | 1 | 1 | 1 | 10 | 30 | 30 | 30 |
| Luminous | 85 | 70 | 50 | 50 | 85 | 70 | 50 |
| transmittance (Y) (%) | | | | | | | |
| Transmission color b* | 0.97 | 1.81 | −0.12 | 0.87 | 0.84 | 1.64 | −0.17 |
| SCI Y (%) | 0.85 | 0.62 | 0.55 | 0.49 | 0.96 | 0.67 | 0.51 |
| SCI L* | 7.71 | 5.59 | 4.99 | 4.42 | 8.65 | 6.09 | 4.61 |
| SCI a* | −0.82 | 1.31 | −0.03 | 0.39 | −4.44 | 0.76 | 9.70 |
| SCI b * | 0.28 | −2.08 | −0.93 | −4.12 | 0.97 | −2.01 | −15.88 |
| SCE Y (%) | 0.23 | 0.18 | 0.10 | 0.12 | 0.39 | 0.27 | 0.21 |
| SCE L* | 2.10 | 1.63 | 0.91 | 1.06 | 3.48 | 2.40 | 1.90 |
| SCE a* | −0.18 | −0.06 | −0.04 | 0.05 | −0.76 | 0.01 | 1.07 |
| SCE b* | 0.5 | 0.35 | 0.12 | −0.53 | 0.21 | −0.07 | −2.34 |
| SCE Y/SCI Y | 0.27 | 0.29 | 0.18 | 0.24 | 0.41 | 0.40 | 0.41 |
| Bright contrast | 2347 | 2414 | 2499 | 2163 | 2093 | 2163 | 2081 |
| Dark contrast | 8977 | 8528 | 5702 | 5729 | 7789 | 7532 | 4794 |
| Sheet resistance (Ω/□) | 1 × 10¹⁰ | 1 × 10¹⁰ | 1 × 10¹⁰ | 1 × 10¹⁰ | 1 × 10¹⁰ | 1 × 10¹⁰ | 1 × 10¹⁰ |

TABLE 2

| | | Example 8 | Example 9 | Example 10 | Example 11 | Example 12 | Example 13 | Example 14 |
|---|---|---|---|---|---|---|---|---|
| Anti- | Kind | Absorption | Absorption | Absorption | Transparent | Transparent | Transparent | Transparent |
| reflective | | AR | AR | AR | AR | AR | AR | AR |
| film | Luminous | 70 | 70 | 50 | 95 | 95 | 95 | 95 |
| | transmittance | | | | | | | |
| | (%) | | | | | | | |
| Transparent | Kind | PET-AG | PET-AG | PET-AG | TAC-HC | TAC-HC | TAC-HC | PET-AG |
| substrate | Product | Manufactured | Manufactured | Manufactured | CHC | CHC | CHC | Manufactured |
| AG layer | name | by REIKO | by REIKO | by REIKO | | | | by REIKO |
| HC layer | | (haze: 50%) | (haze: 60%) | (haze: 80%) | | | | (haze: 50%) |
| Adhesive | Kind | Transparent | Transparent | Transparent | Absorption | Absorption | Absorption | Absorption |
| layer | Product | TD06A | TD06A | TD06A | TD06B | TD06B | TD06B | TD06B |
| | name | | | | | | | |
| | Luminous | 93 | 93 | 93 | 85 | 70 | 50 | 70 |
| | transmittance | | | | | | | |
| | (%) | | | | | | | |

| | | | | | | | |
|---|---|---|---|---|---|---|---|
| Haze (%) | 50 | 60 | 80 | 1 | 2* | 5* | 53* |
| Luminous | 70 | 70 | 50 | 85 | 70 | 50 | 70 |
| transmittance (Y) (%) | | | | | | | |
| Transmission color b* | −1.58 | 1.24 | −0.13 | 0.44 | 0.25 | −0.47 | 1.21 |
| SCI Y (%) | 0.86 | 1.12 | 0.68 | 1.39 | 1.02 | 0.89 | 2.27 |
| SCI L* | 7.77 | 9.93 | 6.15 | 11.91 | 9.19 | 8.07 | 16.87 |
| SCI a* | −1.19 | −0.13 | 0.71 | −1.34 | −2.02 | −1.46 | 0.08 |
| SCI b* | −0.74 | −1.92 | −5.18 | −4.05 | −3.78 | −4.05 | −4.35 |
| SCE Y (%) | 0.63 | 0.83 | 0.61 | 0.32 | 0.30 | 0.33 | 1.44 |
| SCE L* | 5.67 | 7.46 | 5.48 | 2.85 | 2.69 | 3.03 | 12.24 |
| SCE a* | −1.31 | −0.41 | 0.64 | −0.05 | 0.13 | 0.59 | 0.44 |
| SCE b* | −0.22 | −2.36 | −5.29 | 0.49 | 0.41 | 0.44 | −5.25 |
| SCE Y/SCI Y | 0.73 | 0.74 | 0.90 | 0.23 | 0.29 | 0.37 | 0.63 |
| Bright contrast | 1222 | 1027 | 860 | 1712 | 1845 | 868 | 559 |
| Dark contrast | 6101 | 4652 | 4357 | 7572 | 8239 | 5640 | 3693 |
| Sheet resistance (Ω/□) | 1 × 10¹⁰ | 1 × 10¹⁰ | 1 × 10¹⁰ | 1 × 10¹⁰ | 1 × 10¹⁰ | 1 × 10¹⁰ | 1 × 10¹⁰ |

*Haze due to pigment (scattering component) in adhesive is included

Example 1 is different from Example 11 only in that Example 1 includes an anti-reflective film having a light absorption ability, whereas Example 11 includes an adhesive layer having a light absorption ability. In Example 1 including the anti-reflective film having a light absorption ability, a layer having a light absorption ability is provided at a position closer to the surface into which external light enters in a self-luminous display device, so that the anti-reflective film can efficiently absorb the light reflected by the transparent substrate or the adhesive layer. Therefore, Example 1 is more excellent in bright contrast and dark contrast than Example 11 including the adhesive layer having a light absorption ability. The same is true in the case of comparing Example 2 with Example 12, in the case of comparing Example 3 with Example 13, and in the case of comparing Example 8 with Example 14.

In addition, in all of Examples 1 to 10, the luminous transmittance (Y) of the anti-reflective film-attached transparent substrate is within the range of 20% to 90%, so that the anti-reflective film-attached transparent substrate has a moderate light absorption ability and can sufficiently prevent glare of external light as an anti-reflective film-attached transparent substrate for a self-luminous display device.

Although various embodiments have been described above with reference to the drawings, it is needless to say that the present invention is not limited to such examples. It is obvious for a person skilled in the art that various modifications and variations can be made within the category described in the scope of claims and it is understood that such modifications and variations naturally belong to the technical scope of the present invention. Further, the components described in the above embodiment may be combined in any manner without departing from the spirit of the invention.

### REFERENCE SIGNS LIST

10 self-luminous display
20 anti-reflective film-attached transparent substrate
21 adhesive layer
22 transparent substrate
23 anti-glare layer or hard coat layer
24 anti-reflective film
31 cathode
32 OLED light emitting element
33 anode
41 micro LED light emitting element
100 self-luminous display device
200 OLED display device
300 micro LED display device

1. A self-luminous display device comprising an anti-reflective film-attached transparent substrate comprising a transparent substrate and an anti-reflective film on the transparent substrate,
wherein the anti-reflective film has a light absorption ability and has a laminated structure in which at least two dielectric layers having different refractive indices are laminated.

2. The self-luminous display device according to claim 1, wherein the anti-reflective film-attached transparent substrate has a luminous transmittance (Y) of 20% to 90%.

3. The self-luminous display device according to claim 1,
wherein at least one of the dielectric layers is mainly formed of an oxide of Si,
at least another layer among layers in the laminated structure is mainly formed of a mixed oxide of an oxide comprising at least one selected from the group A consisting of Mo and W and an oxide comprising at least one selected from the group B consisting of Si, Nb, Ti, Zr, Ta, Al, Sn, and In, and
a content of elements of the group B contained in the mixed oxide is 65 mass % or less with respect to a total of elements of the group A contained in the mixed oxide and the elements of the group B contained in the mixed oxide.

4. The self-luminous display device according to claim 1, wherein a ratio of a diffuse reflectance (SCE Y) on an outermost surface of the anti-reflective film-attached transparent substrate to a luminous reflectance (SCI Y) on the outermost surface of the anti-reflective film-attached transparent substrate, SCE Y/SCI Y, is 0.15 or more.

5. The self-luminous display device according to claim 1, wherein a luminous reflectance (SCI Y) on an outermost surface of the anti-reflective film-attached transparent substrate is 1.5% or less.

6. The self-luminous display device according to claim 1, wherein a diffuse reflectance (SCE Y) on an outermost surface of the anti-reflective film-attached transparent substrate is 0.05% or more.

7. The self-luminous display device according to claim 1, having a b* value in a transmission color under a D65 light source of 5 or less.

8. The self-luminous display device according to claim 1, having a haze value of 1% or more.

9. The self-luminous display device according to claim 1, wherein the anti-reflective film has a sheet resistance of 10⁴Ω/□ or more.

10. The self-luminous display device according to claim 1, comprising at least one of an anti-glare layer and a hard coat layer between the transparent substrate and the anti-reflective film.

11. The self-luminous display device according to claim 1, further comprising an antifouling film on the anti-reflective film.

12. The self-luminous display device according to claim 1, wherein the transparent substrate comprises a glass.

13. The self-luminous display device according to claim 1, wherein the transparent substrate comprises at least one resin selected from polyethylene terephthalate, a polycarbonate, acrylic, silicone, and triacetyl cellulose.

14. The self-luminous display device according to claim 1, wherein the transparent substrate is a laminate comprising a glass and at least one resin selected from polyethylene terephthalate, a polycarbonate, acrylic, silicone, and triacetyl cellulose.

15. The self-luminous display device according to claim 12, wherein the glass is chemically strengthened.

16. The self-luminous display device according to claim 1, wherein the transparent substrate has been subjected to an anti-glare treatment on a main surface having the anti-reflective film.

17. The self-luminous display device according to claim 1, which is an OLED display device or a micro LED display device.
